(19) United States
(12) Patent Application Publication
(10) Pub. No.: US 2026/0280558 A1
(43) Pub. Date: Sep. 17, 2026

(54) DRIVING CIRCUIT

(71) Applicant: Ancora Semiconductors Inc., Taoyuan City (TW)

(72) Inventor: Wei-Hsiang CHAO, Taoyuan City (TW)

(21) Appl. No.: 19/463,908

(22) Filed: Jan. 29, 2026

Related U.S. Application Data
(60) Provisional application No. 63/769,871, filed on Mar. 11, 2025.

(51) Int. Cl. H03K 17/687; H03K 19/20

(52) U.S. Cl. CPC H03K 17/687; H03K 19/20

(57) ABSTRACT

A driving circuit is provided, including signal input and output terminals, first, second, and third switches, an energy storage circuit, a trigger logic circuit, and a driving logic circuit. The signal input terminal receives an input signal. The signal output terminal outputs a driving signal. The first switch is coupled to the signal input terminal and a first node. The second switch is coupled to the first node, the energy storage circuit, and the driving logic circuit. The third switch is coupled to the first node, a ground terminal, and a third control terminal. The energy storage circuit is coupled to the first switch, the second switch, and the ground terminal. The trigger logic circuit is coupled to a detection terminal and the second switch. The driving logic circuit is coupled to the first, second, and third switches.

### CROSS REFERENCE TO RELATED APPLICATIONS

This application claims the benefit of U.S. provisional application No. 63/769,871, field Mar. 11, 2025, the entirety of which is incorporated by reference herein.

### TECHNICAL FIELD

The present disclosure relates to driving circuits, and, in particular, it relates to driving circuits without external power supplies.

### BACKGROUND

Driving Circuits are commonly used to drive power devices and may be included in integrated circuits. The driving circuits may receive an input signal and output a corresponding output signal to the power devices for further operations. However, signal transmission through the driving circuits may cause delay times or phase differences between the input and output signal, delaying the operations of the power devices.

### BRIEF SUMMARY

The following summary is illustrative only and is not intended to be limiting in any way. That is, the following summary is provided to introduce concepts, highlights, benefits, and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to propose solutions or schemes that address the issue(s) described herein. More specifically, various schemes proposed in the present disclosure are believed to provide solutions pertaining to driving circuits without external power supplies. It is believed that implementations of one or more of the schemes proposed herein may address or otherwise alleviate the issues described above.

An embodiment of the present disclosure provides a driving circuit, comprising a signal input terminal, a signal output terminal, a first switch, a second switch, a third switch, an energy storage circuit, a trigger logic circuit, and a driving logic circuit. The signal input terminal is configured to receive an external input signal. The signal output terminal is coupled to a first node, wherein the signal output terminal is configured to output a driving signal.

The first switch comprises a first terminal coupled to the signal input terminal, a second terminal coupled to the first node, and a first control terminal coupled to the signal input terminal. The second switch comprises a third terminal, a fourth terminal coupled to the first node, and a second control terminal. The third switch comprises a fifth terminal coupled to the first node, a sixth terminal coupled to a ground terminal, and a third control terminal. The energy storage circuit comprises an energy storage input terminal coupled to the first terminal of the first switch, an energy storage output terminal coupled to the third terminal of the second switch, and an energy storage ground terminal coupled to the ground terminal. The trigger logic circuit comprises a trigger logic input terminal coupled to a detection terminal, and a trigger logic output terminal coupled to the second control terminal of the second switch. The driving logic circuit comprises a first driving logic input terminal coupled to the first terminal of the first switch, a second driving logic input terminal coupled to the second control terminal of the second switch, and a driving logic output terminal coupled to the third control terminal of the third switch.

In an embodiment, the first switch comprises a back-to-back N-type metal-oxide semiconductor field effect transistor.

In an embodiment, the energy storage circuit comprises a diode and a capacitor.

In an embodiment, the driving logic circuit comprises a NOR gate.

In an embodiment, the trigger logic circuit is configured to receive an external trigger signal from the detection terminal, and output a switch trigger signal to the second control terminal of the second switch to turn on the second switch.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale, as some components may be shown to be out of proportion to the size in actual implementation, in order to clearly illustrate the concept of the present disclosure

FIGS. 1A and 1B are block diagrams of driving circuits with different implementations of power supplies.

FIG. 2 is a timing diagram of the driving circuits of FIGS. 1A and 1B.

FIG. 3 is a circuit diagram of a driving circuit without external power supplies under the proposed schemes in accordance with the present disclosure.

FIG. 4 is a timing diagram of the driving circuit of FIG. 3 under proposed schemes in accordance with the present disclosure.

FIG. 5 is a circuit diagram of driving circuits without external power supplies under proposed schemes in accordance with the present disclosure.

FIG. 6 is a timing diagram of the driving circuit of FIG. 5 under proposed schemes in accordance with the present disclosure.

### DETAILED DESCRIPTION

Detailed embodiments and implementations of the claimed subject matter are disclosed herein. However, it shall be understood that the disclosed embodiments and implementations are merely illustrative of the claimed subject matter which may be embodied in various forms. The present disclosure may, however, be embodied in many different forms and should not be construed as limited to the exemplary embodiments and implementations set forth herein. Rather, these exemplary embodiments and implementations are provided so that descriptions of the present disclosure are thorough and complete and will fully convey the scope of the present disclosure to those skilled in the art. In the description below, details of well-known features and techniques may be omitted to avoid unnecessarily obscuring the presented embodiments and implementations.

Implementations in accordance with the present disclosure relate to various techniques, methods, schemes, and/or solutions for driving circuits without external power supplies. According to the present disclosure, a number of possible solutions may be implemented separately or jointly. That is, although these possible solutions may be described below separately, two or more of these possible solutions may be implemented in one combination or another.

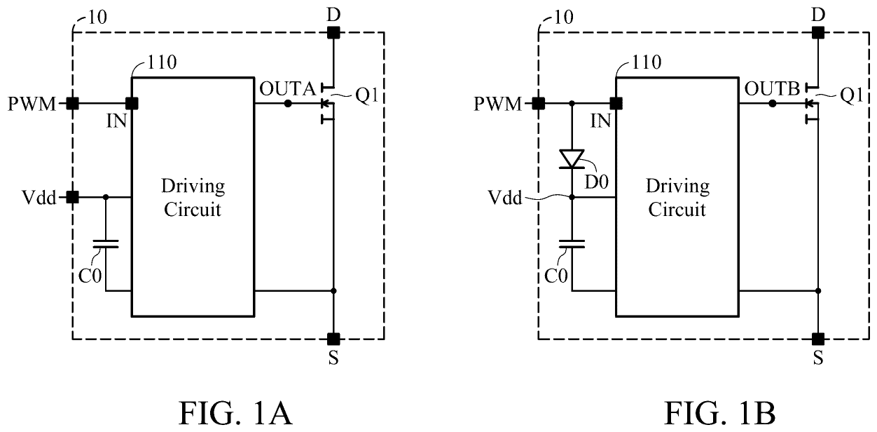

FIGS. 1A and 1B are block diagrams of driving circuits with different implementations of power supplies. Referring to FIG. 1A, an integrated circuit block 10 comprises an input circuit, a driving circuit 110, and a power device. The input circuit includes a power supply terminal for receiving a power supply Vdd from external power sources, a capacitor C0, and a signal input terminal for receiving an external input signal PWM. The driving circuit 110 includes a signal input terminal IN and terminals coupled to the power device and a ground (e.g., a ground terminal of the power device). The power device includes a power transistor Q1 having a drain terminal D, a source terminal S, and a control terminal OUTA. The control terminal OUTA is configured to receive the output signals from the driving circuit 110, and the source terminal S may be coupled to a ground (i.e., be configured as a ground terminal).

The driving circuit 110 of FIG. 1A receives the external input signal PWM through the signal input terminal IN, and outputs a driving signal to the power transistor Q1 through the output terminal. However, this may cause a delay time between the external input signal PWM and the driving signal at the control terminal OUTA.

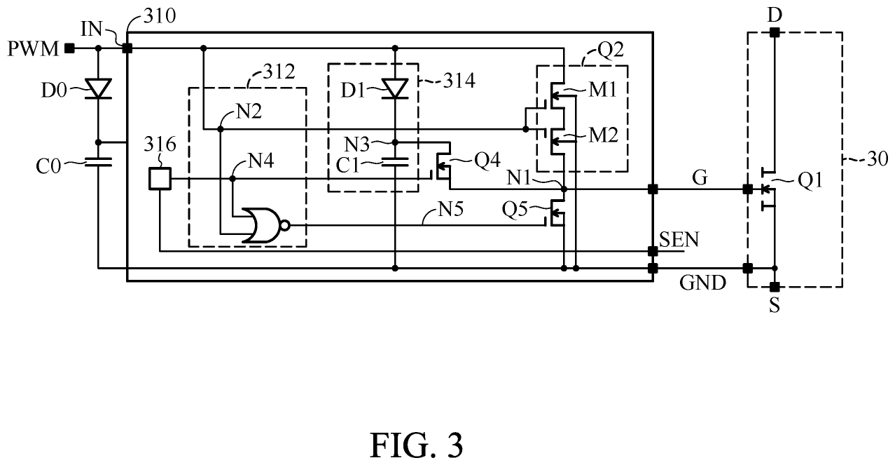

Referring to FIG. 1B, the integrated circuit block 10 has a different power supply implementation compared with FIG. 1A. In FIG. 1B, a diode D0 is add to the input circuit, so that the driving circuit 110 may operate without an external power supply, i.e., the power supply Vdd is now provided by the external input signal PWM. This modification results in an integrated circuit block 10 with less pins and simplifies the design requirements and complexities. However, the voltage level of the power supply Vdd is controlled by the external input signal PWM. That is, the power supply Vdd can drive the driving circuit 110 after the external input signal PWM is received, which may still lead to delay times between the external input signal PWM and the driving signal at the control terminal OUTB. Therefore, some modifications are made to the driving circuit 110 to reduce or eliminate this delay time, while keeping the simplified design of the integrated circuit block 10 of FIG. 1B (which will be described in detail regarding FIGS. 3 to 6).

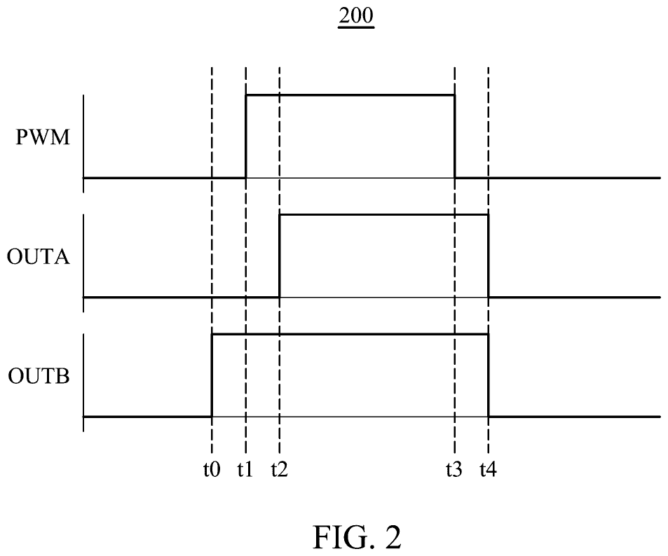

FIG. 2 is a timing diagram of the driving circuit 110 of FIGS. 1A and 1B. The timing diagram shown in FIG. 2 illustrates the voltage (or logic) level of signals at the signal input terminal of integrated circuit block 10 and the control terminals OUTA and OUTB. As described according to FIG. 1A, a delay time occurs between the driving signal at the control terminal OUTA and the external input signal PWM, e.g., the period from times t1 to t2. Additionally, this delay time appears at the end of the cycle. That is, though the external input signal PWM is deactivated at time t3, the power transistor Q1 remains in an ON state (e.g., turned on) until the driving signal is deactivated at time t4. This may cause a dead time and delayed operations of the power transistor Q1, which may increase the power consumption of the power device.

The desired behaviors of the driving signal are provided at the control terminal OUTB (e.g., by driving circuit 110 with further modifications), which shows that the driving signal rises at time t0 before the external input signal PWM is received at time t1. By activating the driving signal before receiving the external input signal PWM, the power transistor Q1 is turned on before receiving the external input signal PWM. Therefore, when the external input signal PWM is received, the power transistor Q1 can react without waiting for a delay time. As a result, the dead time of the power transistor Q1 is reduced or eliminated.

FIG. 3 is a circuit diagram of a driving circuit 310 without external power supplies under proposed schemes in accordance with the present disclosure. The driving circuit 310 receives the external input signal PWM through the signal input terminal IN, while the power supply is provided by the diode D0 and the capacitor C0 coupled in series between the signal input terminal IN and a ground terminal GND. The driving circuit 310 outputs the driving signal through a signal output terminal G, which is coupled to a control terminal of a power device 30. Additionally, the driving circuit 310 receives a detection signal through a detection terminal SEN, and the driving circuit 310 is coupled to the ground through the ground terminal GND.

The driving circuit 310 includes a first switch Q2, a second switch Q4, a third switch Q5, a driving logic circuit 312, an energy storage circuit 314, and a trigger logic circuit 316. The first switch Q2 includes a first terminal coupled to the signal input terminal IN, a second terminal coupled to a node N1, and a control terminal coupled to a node N2. The second switch Q4 includes a first terminal coupled to a node N3, a second terminal coupled to the node N1, and a control terminal coupled to a node N4. The third switch Q5 includes a first terminal coupled to the node N1, a second terminal coupled to the ground terminal GND, and a control terminal coupled to a node N5.

The energy storage circuit 314 includes a diode D1 and a capacitor C1. The diode D1 has a first terminal (also refer to as the energy storage input terminal) couple to the signal input terminal IN and a second terminal (also refer to as the energy storage output terminal) coupled to the node N3. The capacitor C1 has a first terminal coupled to the second terminal of the diode D1 and a second terminal coupled to the ground terminal GND. The driving logic circuit 312 includes a NOR gate, which has a first input terminal (also refer to as the first driving logic input terminal) coupled to the node N2, a second input terminal (also refer to as the second driving logic input terminal) coupled to the node N4, and an output terminal (also refer to as the driving logic output terminal) coupled to the node N5. The trigger logic circuit 316 includes a trigger logic input terminal coupled to the detection terminal SEN, and a trigger logic output terminal coupled to the node N4.

The power device 30 includes a first terminal D, a second terminal S coupled to the ground terminal GND, and a control terminal coupled to the driving circuit 310 to receive the driving signal. The power device also includes the power transistor Q1, which has a drain terminal coupled to the first terminal D, a source terminal coupled to the second terminal S, and a control terminal coupled to the signal output terminal G of the driving circuit 310. In an embodiment, the detection terminal SEN of the driving circuit is coupled to the first terminal D of the power device 30 through a detection circuit (not shown).

That is, the first driving logic input terminal of the driving logic circuit 312 is coupled to the control terminal of the first switch Q2 (both are connected through the node N2 to the signal input terminal IN). The second driving logic input terminal of the driving logic circuit 312 is coupled to the control terminal of the second switch Q4 and the trigger logic output terminal of the trigger logic circuit 316 (all three are connected to the node N4). The energy storage output terminal of the energy storage circuit 314 is coupled to the first terminal of the second switch Q4 (both are connected to the node N3). The driving logic output terminal of the driving logic circuit 312 is coupled to the control terminal of the third switch Q5 (both are connected to the node N5). The second terminal of the first switch Q2, the second terminal of the second switch Q4, and the first terminal of the third switch Q5 are coupled to one another (all three are connected to the node N1).

The first switch Q2 comprises transistors M1 and M2, which form a back-to-back N-type metal-oxide semiconductor field-effect transistor (NMOS) switch that allows or blocks bidirectional current flows. The transistor M1 includes a drain terminal coupled to the first terminal of the first switch Q2, a source terminal, and a control terminal coupled to the node N2. The transistor M2 includes a drain terminal coupled to the second terminal of the first switch Q2, a source terminal coupled to the source terminal of the transistor M1, and a control terminal coupled to the node N2. It should be noted that, though in FIG. 3, the transistors M1 and M2 are configured to have their source terminals coupled to each other, in another implementation, the transistors M1 and M2 may be configured to have their drain terminals coupled to each other.

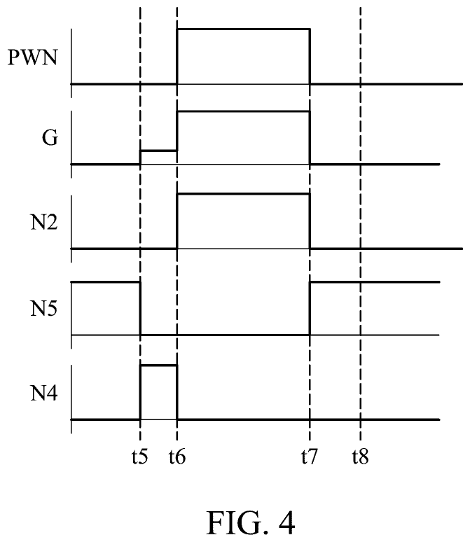

FIG. 4 is a timing diagram of the driving circuit 310 of FIG. 3 under the proposed schemes in accordance with the present disclosure. In FIG. 4, the timing diagram shows the voltage levels of the signals at the signal input terminal IN (i.e., the external input signal PWM), the signal output terminal G, and the nodes N2, N4, and N5. The external input signal PWM is activated (or received) at time t6. Before time t6, the energy storage circuit 314 pre-charges the power transistor Q1 to a threshold voltage through the second switch Q4 and the signal output terminal G at time t5. The power for the pre-charge is stored in the capacitor C1. Therefore, the power transistor Q1 is pre-charged to its threshold voltage and can be turned on immediately once the driving circuit 310 outputs the driving signal. As a result, the dead time of the power device 30 is reduced, leading to a reduced power consumption.

To accomplish the pre-charge of the power transistor Q1, energies has to be stored in the capacitor C1. That is, before the pre-charge begins, the second switch Q4 has to be turned off. Therefore, the trigger logic circuit 316 is configured to output a trigger logic signal to turn off the second switch Q4, such as in FIG. 4, before the pre-charge starts at time t5, the voltage level at the node N4 remains at a low level to turn off the second switch Q4. Then, at time t5, the trigger logic circuit 316 receives the detection signal through the detection terminal SEN from an external signal source (e.g., another circuit configured to control the operations of the power device 30 and/or the driving circuit 310, such as a detection circuit coupled to the first terminal D of the power device 30).

The trigger logic circuit 316 outputs the trigger logic signal with a high level to turn on the second switch Q4. Additionally, since the external input signal PWM is not activated before time t6, the voltage level of the node N2 remains at a low level. The driving logic circuit 312 receives a low-level input signal from the node N2 and a high-level input signal from the node N4 to generate a low-level output signal at the node N5. That is, the second switch Q4 and the ground terminal GND is disconnected. Therefore, the third switch Q5 is turned off, and a conductive path is formed from the energy storage output terminal (i.e., node N3), through the second switch Q4, to the signal output terminal G. As a result, the power transistor Q1 is pre-charged by the energy storage circuit 314.

Then, at time t6, the external input circuit PWM is activated (or received), causing the voltage level at the node N2 to rise. Therefore, the first switch Q2 is turned on, forming a conductive path from the signal input terminal IN to the signal output terminal G to output the driving signal corresponding to the external input signal PWM. As a result, the delay time between the driving signal and the external input signal may be reduced or eliminated.

Additionally, the third switch Q5 have to be turned off. Therefore, the trigger logic circuit 316 outputs the low-level trigger logic signal to the node N4. The driving logic circuit 312 receives a high-level input signal from the node N2 and a low-level input signal from the node N4, thereby generating a low-level output signal at the node N5 to turn off the third switch Q5. As a result, the node N1 (and the signal output terminal G) is disconnected from the ground terminal GND.

The second switch Q4 will also be turned off, since the voltage level at the node N4 drops to a low level. Therefore, the energy storage output terminal and the signal output terminal G are disconnected, and the capacitor C1 may recharge for the next pre-charge operation.

Next, at time t7, the external input signal PWM is deactivated, causing the voltage level at the node N2 to drop to a low level. Therefore, the first switch Q2 is turned off, and the driving logic circuit 312 receives low-level input signals from both nodes N2 and N4. As a result, the voltage level at the node N5 rises to a high level and turns on the third switch Q5, causing the node N1 (and the signal output terminal G) to be connected to the ground terminal GND. This leads to a rapid drop in the voltage level of the driving signal, and may turns off the power transistor Q1 immediately, stopping the operations of the power device 30 as soon as the external input signal PWM. As a result, the delayed operations (e.g., might keep operate until time t8) of the power device 30 is reduced or eliminated.

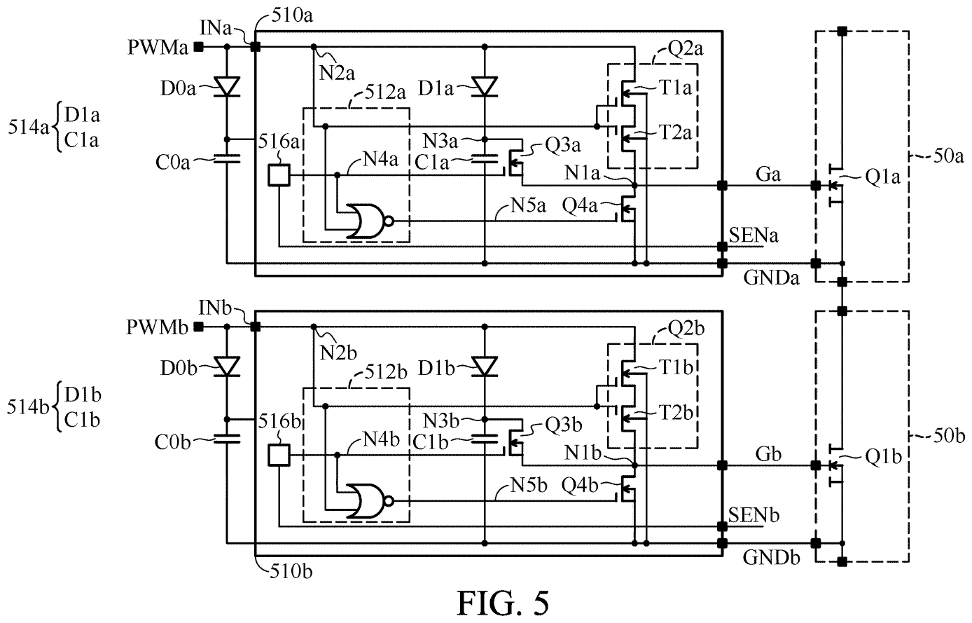

FIG. 5 is a circuit diagram of driving circuits 510a and 510b without external power supplies under the proposed schemes in accordance with the present disclosure. Similar to the driving circuit 310 in FIG. 3, the driving circuit 510a receives an external input signal PWMa through a signal input terminal INa, while the power supply is provided by a diode D0a and a capacitor C0a coupled in series between the signal input terminal INa and a ground terminal GNDa. The driving circuit 510a outputs the driving signal through a signal output terminal Ga, which is coupled to a control terminal of a power device 50a. Additionally, the driving circuit 510a receives a detection signal through a detection terminal SENa, and the driving circuit 510a is coupled to the ground through the ground terminal GNDa.

The driving circuit 510a includes a first switch Q2a, a second switch Q4a, a third switch Q5a, a driving logic circuit 512a, an energy storage circuit 514a, and a trigger logic circuit 516a. The first switch Q2a includes a first terminal coupled to the signal input terminal INa, a second terminal coupled to a node N1a, and a control terminal coupled to a node N2a. The second switch Q4a includes a first terminal coupled to a node N3a, a second terminal coupled to the node N1a, and a control terminal coupled to a node N4a. The third switch Q5a includes a first terminal coupled to the node N1a, a second terminal coupled to the ground terminal GNDa, and a control terminal coupled to a node N5a.

The energy storage circuit 514a includes a diode D1a and a capacitor C1a. The diode D1a has a first terminal (also refer to as the energy storage input terminal) couple to the signal input terminal INa and a second terminal (also refer to as the energy storage output terminal) coupled to the node N3a. The capacitor C1a has a first terminal coupled to the second terminal of the diode D1a and a second terminal coupled to the ground terminal GNDa. The driving logic circuit 512a includes a NOR gate, which has a first input terminal (also refer to as the first driving logic input terminal) coupled to the node N2a, a second input terminal (also refer to as the second driving logic input terminal) coupled to the node N4a, and an output terminal (also refer to as the driving logic output terminal) coupled to the node N5a. The trigger logic circuit 516a includes a trigger logic input terminal coupled to the detection terminal SENa, and a trigger logic output terminal coupled to the node N4a.

The power device 50a includes a first terminal, a second terminal, and a control terminal coupled to the driving circuit 510a to receive the driving signal. The power device 50a also includes a power transistor Q1a, which has a drain terminal coupled to the first terminal of the power device 50a, a source terminal coupled to the second terminal of the power device 50a, and a control terminal coupled to the signal output terminal Ga of the driving circuit 510a. In an embodiment, the first terminal of the power device 50a is coupled to the detection terminal SENa through a detection circuit (not shown).

Similarly, the driving circuit 510b receives an external input signal PWMb through a signal input terminal INb, while the power supply is provided by a diode D0b and a capacitor C0b coupled in series between the signal input terminal INb and a ground terminal GNDb. The driving circuit 510b outputs the driving signal through a signal output terminal Gb, which is coupled to a control terminal of a power device 50b. Additionally, the driving circuit 510b receives a detection signal through a detection terminal SENb, and the driving circuit 510b is coupled to the ground through the ground terminal GNDb. In an embodiment, the detection terminal SENb is coupled to the first terminal of the power device 50b.

The driving circuit 510b includes a first switch Q2b, a second switch Q4b, a third switch Q5b, a driving logic circuit 512b, an energy storage circuit 514b, and a trigger logic circuit 516b. The first switch Q2b includes a first terminal coupled to the signal input terminal INb, a second terminal coupled to a node N1b, and a control terminal coupled to a node N2b. The second switch Q4b includes a first terminal coupled to a node N3b, a second terminal coupled to the node N1b, and a control terminal coupled to a node N4b. The third switch Q5b includes a first terminal coupled to the node N1b, a second terminal coupled to the ground terminal GNDb, and a control terminal coupled to a node N5b.

The energy storage circuit 514b includes a diode D1b and a capacitor C1b. The diode D1b has a first terminal (also refer to as the energy storage input terminal) couple to the signal input terminal INb and a second terminal (also refer to as the energy storage output terminal) coupled to the node N3b. The capacitor C1a has a first terminal coupled to the second terminal of the diode D1b and a second terminal coupled to the ground terminal GNDb. The driving logic circuit 512b includes a NOR gate, which has a first input terminal (also refer to as the first driving logic input terminal) coupled to the node N2b, a second input terminal (also refer to as the second driving logic input terminal) coupled to the node N4b, and an output terminal (also refer to as the driving logic output terminal) coupled to the node N5b. The trigger logic circuit 516b includes a trigger logic input terminal coupled to the detection terminal SENb, and a trigger logic output terminal coupled to the node N4b.

The power device 50b includes a first terminal coupled to the second terminal of the power device 50a, a second terminal coupled to the ground terminal GNDb, and a control terminal coupled to the driving circuit 510b to receive the driving signal. The power device 50b also includes a power transistor Q1b, which has a drain terminal coupled to the first terminal of the power device 50b, a source terminal coupled to the second terminal of the power device 50b, and a control terminal coupled to the signal output terminal Gb of the driving circuit 510b.

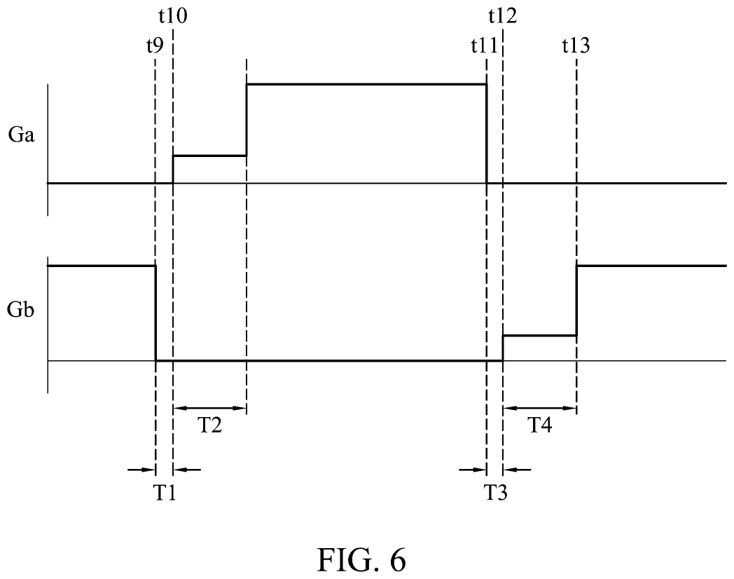

FIG. 6 is a timing diagram of the driving circuits 510a and 510b of FIG. 5 under the proposed schemes in accordance with the present disclosure. The detailed operations of driving circuits 510a and 510b are similar to the driving circuit 310, and thus will not be repeated herein. As shown in FIG. 6, the voltage levels at the signal output terminals Ga and Gb start at a low level and a high level, respectively. At time t9, both the power devices 50a and 50b are initiated for the next operation, causing the voltage levels of both signal output terminals Ga and Gb to drop to a low level (e.g., is deactivated). A dead time T1 is past before the next operation starts (e.g., such as an external circuit outputs a detection signal to the detection terminal SENa of the driving circuit 510a). At time t10, the power transistor Q1a of the power device 50a is pre-charged, causing the voltage level at the signal output terminal Ga to rise to a threshold voltage. As a result, the original dead time, which can be T1+T2, is reduced to T1, leading to a reduced power consumption of the power device 50a.

Then, the external input signal PWMa is activated (or received), turning on the first switch Q2a of the driving circuit 510a to output the driving signal to the power device 50a through the signal output terminal Ga, reducing the delay time of the power device 50a (as described based on the driving circuit 310). At time t11, the external input signal PWMa is deactivated, turning off the first switch Q2a and turning on the third switch Q5a. Therefore, the voltage level at the signal output terminal Ga drops to a low level as soon as the external input signal PWMa is deactivated, stopping the operations of the power device 50a. This reduces or eliminates the delayed operating time of the power device 50a.

At time t12, the power device 50b is pre-charged, reducing the dead time from T3+T4 to T3. Then, the power device 50b is activated as soon as the external input signal PWMb is activated. Additionally, when the external input signal PWMb is deactivated, the voltage level at the signal output terminal Gb drops to a low level, stopping the operations of the power device 50b. This reduces or eliminates the delayed operating time of the power device 50b.

By introducing the proposed mechanisms of the driving logic circuits and the trigger logic circuits, the switches of the proposed driving circuit can be turned on or off to create different connections between the energy storage circuit, the power device, the signal input/output terminals, and the ground terminal. As a result, the proposed driving circuit can be configured to pre-charge the power devices to reduce the dead time and the delay start time of the power devices, and can further be configured to deactivate the power devices as soon as the external input signal is deactivated, reducing the delayed operation time of the power devices.

The herein-described subject matter sometimes illustrates different components contained within, or connected with, different other components. It is to be understood that such depicted architectures are merely examples and that, in fact, many other architectures can be implemented that achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components, wirelessly interactable and/or wirelessly interacting components, and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

1. A driving circuit, comprising:
a signal input terminal, configured to receive an external input signal;
a signal output terminal, coupled to a first node, wherein the signal output terminal is configured to output a driving signal;
a first switch, comprising:
a first terminal, coupled to the signal input terminal;
a second terminal, coupled to the first node; and
a first control terminal, coupled to the signal input terminal;
a second switch, comprising:
a third terminal;
a fourth terminal, coupled to the first node; and
a second control terminal;
a third switch, comprising:
a fifth terminal, coupled to the first node;
a sixth terminal, coupled to a ground terminal; and
a third control terminal;
an energy storage circuit, comprising:
an energy storage input terminal, coupled to the first terminal of the first switch;
an energy storage output terminal, coupled to the third terminal of the second switch; and
an energy storage ground terminal, coupled to the ground terminal;
a trigger logic circuit, comprising:
a trigger logic input terminal, coupled to a detection terminal; and
a trigger logic output terminal, coupled to the second control terminal of the second switch; and
a driving logic circuit, comprising:
a first driving logic input terminal, coupled to the first terminal of the first switch;
a second driving logic input terminal, coupled to the second control terminal of the second switch; and
a driving logic output terminal, coupled to the third control terminal of the third switch.

2. The driving circuit as claimed in claim 1, wherein the first switch comprises a back-to-back N-type metal-oxide semiconductor field effect transistor.

3. The driving circuit as claimed in claim 1, wherein the first switch further comprises:
a first transistor, comprising:
a first drain terminal, coupled to the signal input terminal;
a first source terminal; and
a first gate terminal, coupled to the first driving logic input terminal of the driving logic circuit;
a second transistor, comprising:
a second drain terminal, coupled to the first node;
a second source terminal, coupled to the first source terminal of the first transistor; and
a second gate terminal, coupled to the first gate terminal of the first transistor,
wherein the first transistor and the second transistor are configured to have the same type.

4. The driving circuit as claimed in claim 1, wherein the energy storage circuit comprises a diode and a capacitor.

5. The driving circuit as claimed in claim 4, wherein the diode is coupled between the first terminal of the first switch and the third terminal of the second switch, and the capacitor is coupled between the third terminal of the second switch and the ground terminal.

6. The driving circuit as claimed in claim 1, wherein the driving logic circuit comprises a NOR gate.

7. The driving circuit as claimed in claim 6, wherein the NOR gate comprises a first NOR input terminal coupled to the first terminal of the first switch, a second NOR input terminal coupled to the second control terminal of the second switch, and a NOR output terminal coupled to the third control terminal of the third switch.

8. The driving circuit as claimed in claim 1, wherein the trigger logic circuit is configured to:
receive an external trigger signal from the detection terminal; and
output a switch trigger signal to the second control terminal of the second switch to turn on the second switch.

9. The driving circuit as claimed in claim 8, wherein the energy storage circuit outputs a power signal to the signal output terminal in response to the second switch being turned on.

10. The driving circuit as claimed in claim 1, wherein the driving signal is configured to drive an integrated power device.
